(19) United States
(12) Patent Application Publication
(10) Pub. No.: US 2022/0069112 A1
(43) Pub. Date: Mar. 3, 2022

(54) SEMICONDUCTOR DEVICE AND MANUFACTURING METHOD THEREFOR

(71) Applicant: FUJITSU LIMITED, Kawasaki-shi (JP)

(72) Inventors: Shirou OZAKI, Yamato (JP); Junji KOTANI, Atsugi (JP); Atsushi YAMADA, Hiratsuka (JP)

(73) Assignee: FUJITSU LIMITED, Kawasaki-shi (JP)

(21) Appl. No.: 17/228,002

(22) Filed: Apr. 12, 2021

(30) Foreign Application Priority Data
Aug. 25, 2020 (JP) 2020-141973

(51) Int. Cl. H01L 29/778; H01L 29/20; H01L 29/205; H01L 21/02; H01L 29/66

(52) U.S. Cl. CPC H01L 29/7786; H01L 29/2003; H01L 29/205; H01L 29/66462; H01L 21/02458; H01L 21/02502; H01L 21/0254; H01L 21/02389

(57) ABSTRACT

A semiconductor device includes an AlN substrate, a semiconductor laminated structure, disposed above the substrate, and including an electron transit layer and an electron supply layer made of a nitride semiconductor, respectively, and a gate electrode, a source electrode, and a drain electrode disposed above the electron supply layer. The electron transit layer is located at a lowermost position of the semiconductor laminated structure. The gate electrode has a gate length of 0.3 μm or less, and a ratio of a thickness of the semiconductor laminated structure with respect to the gate length of the gate electrode is 4.0 or less.

### CROSS-REFERENCE TO RELATED APPLICATIONS

This application is based upon and claims the benefit of priority of the prior Japanese Patent Application No. 2020-141973, filed on Aug. 25, 2020, the entire contents of which are incorporated herein by reference.

### FIELD

The embodiments discussed herein are related to semiconductor devices, and manufacturing methods therefor.

### BACKGROUND

Nitride semiconductors have properties, such as high saturation electron velocities, wide band gaps, or the like. For this reason, various studies have been made to utilize these features and apply the nitride semiconductors to high-voltage and high-power semiconductor devices. In recent years, techniques related to GaN-based High Electron Mobility Transistors (HEMTs) have been developed.

In one example of the GaN-based HEMT, GaN is used for an electron transit layer, and AlGaN is used for an electron supply layer. A high concentration of 2-Dimensional Electron Gas (2DEG) is generated in the electron supply layer, due to piezo polarization and spontaneous polarization in the GaN. For this reason, the application of the GaN-based HEMTs to high-power amplifiers and high-efficiency switching devices are expected.

In order to use the HEMTs in the high-frequency devices, it is preferable to shorten a gate length.

In conventional semiconductor devices, shortening the gate length facilitates off-leak current flow. In addition, if a thickness the electron transit layer is reduced in order to reduce the off-leak current, current collapse more easily occurs.

Related art may include International Publication Pamphlet No. WO 2009/001888, and Japanese Laid-Open Patent Publication No. 2015-185809, for example.

### SUMMARY

Accordingly, it is an object in one aspect of the embodiments to provide a semiconductor device and a manufacturing method therefor, which can reduce the off-leak current and the current collapse.

According to one aspect of the embodiments, a semiconductor device includes an AIN substrate; a semiconductor laminated structure, disposed above the substrate, and including an electron transit layer and an electron supply layer made of a nitride semiconductor, respectively; and a gate electrode, a source electrode, and a drain electrode disposed above the electron supply layer, wherein the electron transit layer is located at a lowermost position of the semiconductor laminated structure, the gate electrode has a gate length of 0.3 μm or less, and a ratio of a thickness of the semiconductor laminated structure with respect to the gate length of the gate electrode is 4.0 or less.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a cross sectional view illustrating a semiconductor device according to a reference example.

FIG. 2 is a cross sectional view illustrating a semiconductor device according to a first embodiment.

FIG. 3 is a cross sectional view (part 1) illustrating a method for manufacturing the semiconductor device according to the first embodiment.

FIG. 4 is a cross sectional view (part 2) illustrating the method for manufacturing the semiconductor device according to the first embodiment.

FIG. 5 is a cross sectional view (part 3) illustrating the method for manufacturing the semiconductor device according to the first embodiment.

FIG. 6 is a cross sectional view (part 4) illustrating the method for manufacturing the semiconductor device according to the first embodiment.

FIG. 7 is a cross sectional view (part 5) illustrating the method for manufacturing the semiconductor device according to the first embodiment.

FIG. 8 is a cross sectional view illustrating the semiconductor device according to a second embodiment.

FIG. 9 is a diagram illustrating results of a first experiment.

FIG. 10 is a diagram illustrating the results of a second experiment.

FIG. 11 is a diagram illustrating the results of a third experiment for a sample A.

FIG. 12 is a diagram illustrating the results of the third experiment for a sample B.

FIG. 13 is a diagram illustrating the results of the third experiment for a sample C.

FIG. 14 is a diagram illustrating collapse rates of the sample A, the sample B, and the sample C.

FIG. 15 is a diagram illustrating a discrete package according to a third embodiment.

FIG. 16 is a circuit diagram illustrating a PFC circuit according to a fourth embodiment.

FIG. 17 is a circuit diagram illustrating a power supply device according to a fifth embodiment.

FIG. 18 is a circuit diagram illustrating an amplifier according to a sixth embodiment.

### DESCRIPTION OF EMBODIMENTS

Preferred embodiments of the present invention will be described with reference to the accompanying drawings. In the present specification and the drawings, constituent elements having substantially the same functions may be designated by the same reference numerals, and a repeated description thereof may be omitted.

### Reference Example

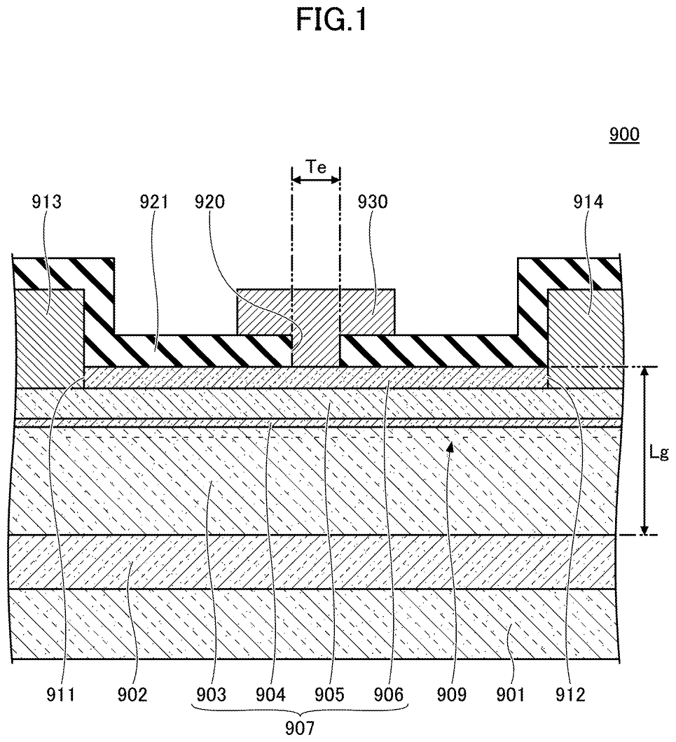

First, a reference example will be described. FIG. 1 is a cross sectional view illustrating a semiconductor device according to a reference example.

A semiconductor device 900 according to the reference example includes a SiC substrate 901, a AlGaN buffer layer 902 formed on the substrate 901, and a semiconductor laminated structure 907 formed on the buffer layer 902, as illustrated in FIG. 1. The semiconductor laminated structure 907 includes an i-GaN electron transit layer 903, an i-AlGaN spacer layer 904, an n-AlGaN electron supply layer 905, and an n-GaN cap layer 906. A dislocation density of the substrate 901 may be approximately 1.0×10⁸ cm⁻² to approximately 1.0×10¹⁰ cm⁻², and a dislocation density of the buffer layer 902 may be approximately 1.0×10⁸ cm⁻² to approximately 1.0×10¹⁰ cm⁻². An Al composition of the buffer layer 902 may be 5%, and a thickness of the buffer layer 902 may be 300 μm. In addition, a thickness Te of the semiconductor laminated structure 907 may be 1.0 μm.

Openings 911 and 912 are formed in the cap layer 906, a source electrode 913 is formed inside the opening 911, and a drain electrode 914 is formed inside the opening 912. A SiN passivation film 921, covering the source electrode 913 and the drain electrode 914, is formed on cap layer 906. An opening 920 is formed in the passivation film 921, at a position between the source electrode 913 and the drain electrode 914 in a plan view. A gate electrode 930, which makes contact with the cap layer 906 via the opening 920, is formed on the passivation film 921. A width of the opening 920 may be 0.1 μm, and a gate length Lg of the gate electrode 930 may be 0.1 μm or less.

In the semiconductor device 900, a 2-Dimensional Electron Gas (2DEG) 909 is generated near an upper surface of the electron transit layer 903. When a predetermined voltage is applied to the gate electrode 930, a depletion layer spreads in the semiconductor laminated structure 907, and a portion of the 2DEG 209 dissipates, thereby putting the semiconductor device 900 in an off state.

However, a thickness of the semiconductor laminated structure 907 is 1.0 μm, and the depletion layer does not reach a lower end of the semiconductor laminated structure 907. For this reason, electrons bypassing near a lower surface of the electron transit layer 903 are present, thereby causing an off-leak current to flow.

A thickness of the electron transit layer 903 may be reduced so that the depletion layer reaches the lower end of the semiconductor laminated structure 907. However, in the case where the thickness of the electron transit layer 903 is reduced, a dislocation of the buffer layer 902 acts as an electron trap in an on state of the semiconductor device 900, thereby increasing the current collapse.

The present inventors made diligent studies for reducing the off-leak current and the current collapse. As a result of such studies, it was found that the off-leak current and the current collapse can be reduced, by using an AIN substrate, and setting a ratio of the thickness Te of the semiconductor laminated structure with respect to the gate length Lg to a value which falls within a predetermined range.

### First Embodiment

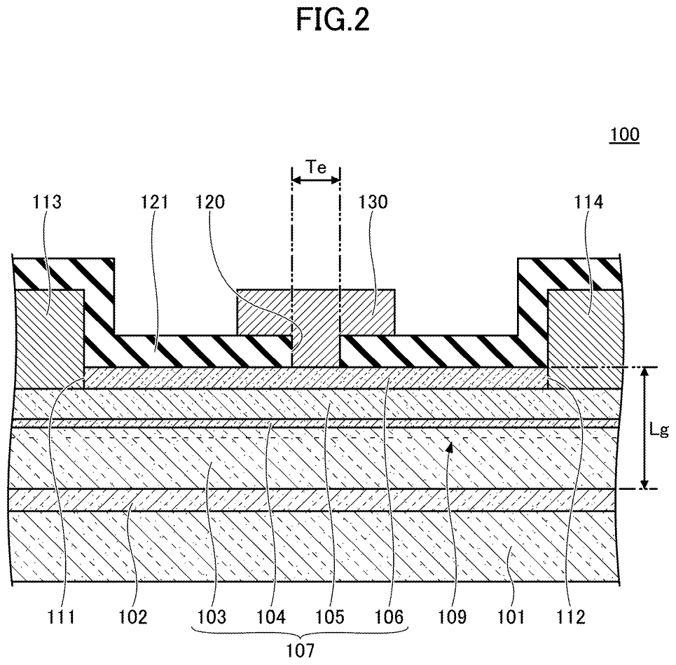

Next, a first embodiment will be described. The first embodiment relates to a semiconductor device including a High Electron Mobility Transistor (HEMT). FIG. 2 is a cross sectional view illustrating a semiconductor device according to the first embodiment.

A semiconductor device 100 according to the first embodiment includes an AlN substrate 101, a buffer layer 102 formed on the substrate 101, and a semiconductor laminated structure 107 formed on the buffer layer 102, as illustrated in FIG. 2. The semiconductor laminated structure 107 includes an electron transit layer 103 made of a nitride semiconductor, a spacer layer 104, an electron supply layer 105, and a cap layer 106, for example. The buffer layer 102 may be an AlₓGa₁₋ₓN layer having a thickness of 100 nm or less, for example. An Al composition x of the buffer layer 102 may be 0.2 or higher, for example. The electron transit layer 103 may be a GaN layer (i-GaN layer) which is not intentionally doped with impurities, for example. The spacer layer 104 may be an AlGaN layer (i-AlGaN layer) having a thickness of 4 nm to 6 nm, and not intentionally doped with impurities, for example. The electron supply layer 105 may be an n-type AlGaN layer (n-AlGaN layer) having a thickness of 25 nm to 35 nm, for example. The cap layer 106 may be an n-type GaN layer (n-GaN layer) having a thickness of 1 nm to 10 nm, for example. A thickness L11 of the semiconductor laminated structure 107 may be 1.2 μm or less, for example. The electron supply layer 105 and the cap layer 106 may be Si-doped with a concentration of approximately 5×10¹⁸ cm⁻³, for example.

For example, a dislocation density of the AlN substrate 101 may be 10³ cm⁻² or less, and a dislocation density of the AlₓGa₁₋ₓN buffer layer 102 may also be 10⁵ cm⁻² or less. The dislocation density of the AlN substrate 101 may be in a range of 10⁴ cm⁻² or greater and 10⁵ cm⁻² or less and the dislocation density of the AlₓGa₁₋ₓN buffer layer 102 may be in a range of 10⁴ cm⁻² or greater and 10⁵ cm⁻² or less.

Openings 111 and 112 are formed in the cap layer 106, a source electrode 113 is formed inside the opening 111, and a drain electrode 114 is formed inside the opening 112. A passivation film 121, covering the source electrode 113 and the drain electrode 114, is formed on the cap layer 106. The passivation film 121 may be a SiN film having a thickness of 10 nm to 100 nm, for example. An opening 120 is formed in the passivation film 121, at a position between the source electrode 113 and the drain electrode 114 in the plan view. A gate electrode 130, which makes contact with the cap layer 106 via the opening 120, is formed on the passivation film 121. A width of the opening 120 may be 0.3 μm or less, and a gate length L12 of the gate electrode 130 may be 0.3 μm or less. A ratio of a thickness Te of the semiconductor laminated structure 107 with respect to a gate length Lg of the gate electrode 130 may be 4.0 or less.

The source electrode 113 and the drain electrode 114 may be made of a metal, and may include a laminate of a titanium (Ti) film and an aluminum (Al) film, for example. The gate electrode 130 may have the so-called T-shaped structure. The gate electrode 130 may be made of a metal, and may include a laminate of a nickel (Ni) film and a gold (Au) film, for example.

In the semiconductor device 100, a 2DEG 109 is generated near an upper surface of the electron transit layer 103. When a predetermined voltage is applied to the gate electrode 130, a depletion layer spreads in the semiconductor laminated structure 107, and a portion of the 2DEG 109 dissipates, thereby putting the semiconductor device 100 in an off state. In this state, because the ratio of the thickness Te of the semiconductor laminated structure 107 with respect to the gate length Lg of the gate electrode 130 is 4.0 or less, the depletion layer reaches a lower end of the semiconductor laminated structure 107. For this reason, it is possible to reduce electrons bypassing near a lower surface of the electron transit layer 103, thereby reducing the off-leak current.

In addition, because the Al composition x of the buffer layer 102 is 0.2 or higher, the buffer layer 102 can function as a back barrier with respect to the electron transit layer 103. Moreover, because the thickness of the buffer layer 102 is 100 nm or less, the AlN substrate 101 can also function as a back barrier with respect to the electron transit layer 103. Accordingly, the off-leak current can also be reduced by the back barriers of the buffer layer 102 and the substrate 101.

Further, in this embodiment, the electron transit layer 103 is formed on the AlₓGa₁₋ₓN buffer layer 102 which is formed on the AlN substrate 101. For this reason, although the dislocation density of the buffer layer 102 is low and the electron transit layer 103 is thin to an extent such that the depletion layer reaches the lower end of the semiconductor laminated structure 107, it is possible to reduce generation of the current collapse.

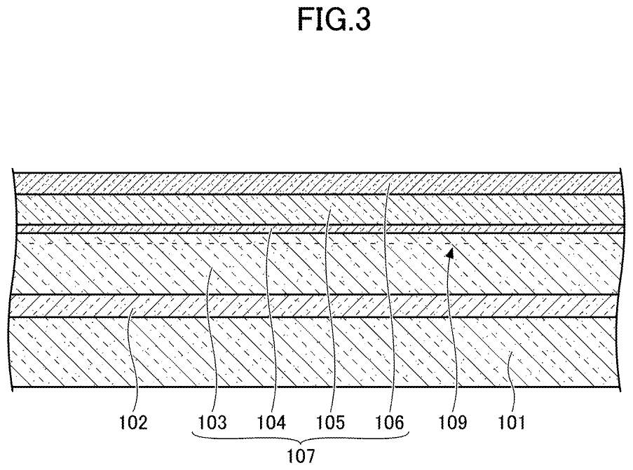

Next, a method for manufacturing the semiconductor device 100 according to the first embodiment will be described. FIG. 3 through FIG. 7 are cross sectional views illustrating the method for manufacturing the semiconductor device 100 according to the first embodiment.

First, as illustrated in FIG. 3, the buffer layer 102 is formed on the substrate 101, and the semiconductor laminated structure 107, including the electron transit layer 103, the spacer layer 104, the electron supply layer 105, and the cap layer 106, is formed on the buffer layer 102. The buffer layer 102 and the semiconductor laminated structure 107 may be formed by Metal Organic Vapor Phase Epitaxy (MOVPE), for example. As a result, the 2DEG 109 is generated near the upper surface of the electron transit layer 103.

When forming the buffer layer 102 and the semiconductor laminated structure 107, a gas mixture of a trimethylaluminum (TMA) gas which is an Al source, a trimethylgallium (TMG) gas which is a Ga source, and an ammonia (NH₃) gas which is a N source, for example, may be used. In this state, the presence or absence of the supply and the flow rate of the trimethylaluminum gas and the trimethylgallium gas may be appropriately set, according to the composition of the nitride semiconductor layer to be deposited. The flow rate of the ammonia gas, which is a common source material for each of the nitride semiconductor layers, may be approximately 100 ccm to approximately 10 LM, for example. Moreover, a deposition pressure may be approximately 50 Torr to approximately 300 Torr, and a deposition temperature may be approximately 1000° C. to approximately 1200° C., for example. Further, when depositing an n-type nitride semiconductor layer (for example, the electron supply layer 105 and the cap layer 106), a SiH₄ gas including Si, for example, is added to the gas mixture at a predetermined flow rate, thereby doping the nitride semiconductor layer with Si. The Si doping concentration may be approximately 1×10¹⁸ cm⁻³ to approximately 1×10²⁰ cm⁻³, for example.

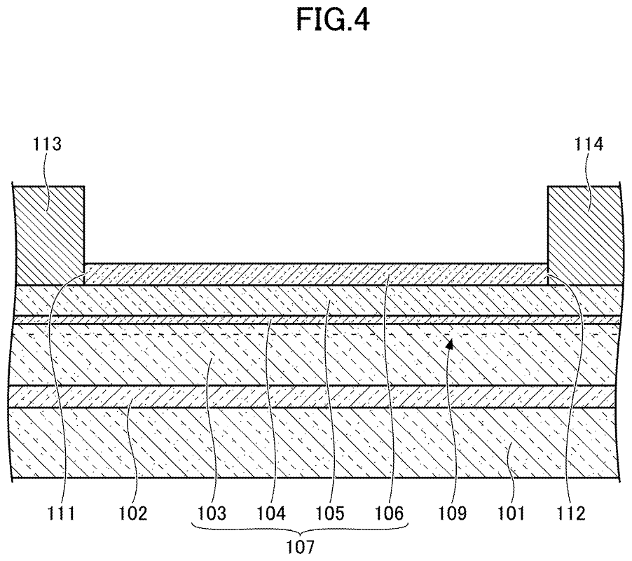

Next, as illustrated in FIG. 4, the openings 111 and 112 are formed in the cap layer 106, the source electrode 113 is formed inside the opening 111, and the drain electrode 114 is formed inside the opening 112. For example, the openings 111 and 112 may be formed by a dry etching using a chlorine-based gas, by providing a resist film having openings respectively formed in regions where the source electrode 113 and the drain electrode 114 are to be formed using a photolithography technique. Further, a metal film may be formed by deposition using the resist film as a deposition mask, and the resist film may be removed together with the metal film thereon, for example, thereby forming the source electrode 113 and the drain electrode 114 inside the respective openings in the resist film. In other words, the source electrode 113 and the drain electrode 114 may be formed by a lift-off method. When forming the metal film, an Al film may be formed after forming a Ti film, for example. After removing the resist film, a heat treatment may be performed at 400° C. to 1000° C. in a nitrogen atmosphere, for example, thereby establishing ohmic properties.

Before forming the openings 111 and 112, device isolation regions may be formed to define device regions in the semiconductor laminated structure 107. When forming the device isolation regions, a photoresist pattern, exposing regions where the device isolation regions are to be formed, are formed on the cap layer 106, for example, and an ion implantation of ions, such as Ar or the like, is performed using this photoresist pattern as a mask. A dry etching using a chlorine-based gas may be performed using this photoresist pattern as an etching mask. In the device isolation regions, the 2DEG 109 is dissipated.

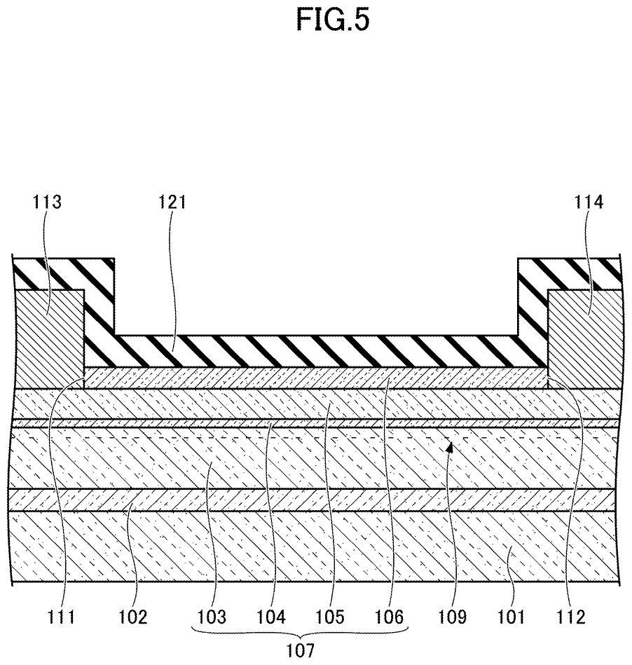

After forming the source electrode 113 and the drain electrode 114, the passivation film 121, covering the source electrode 113 and the drain electrode 114, is formed on the cap layer 106, as illustrated in FIG. 5. The passivation film 121 may be formed by a plasma Chemical Vapor Deposition (CVD), for example. The passivation film 121 may be formed by an Atomic Layer Deposition (ALD) or a sputtering.

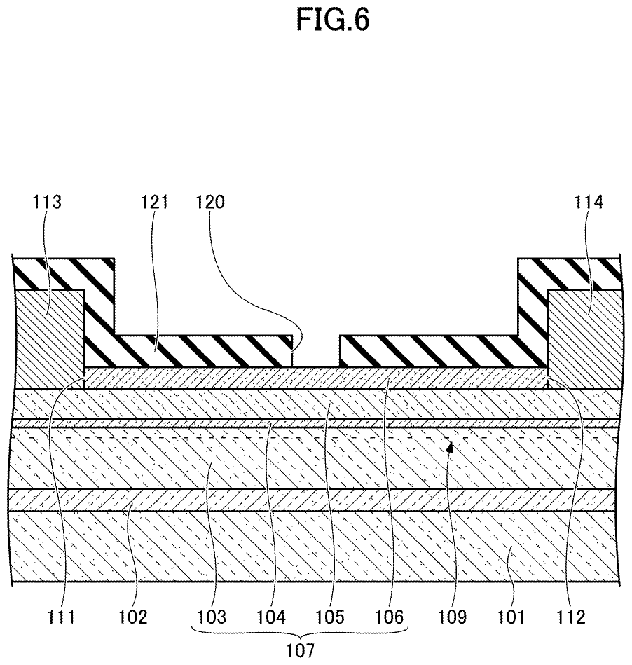

Next, as illustrated in FIG. 6, the opening 120 is formed in the passivation film 121. When forming the opening 120, a photoresist pattern, exposing a region where the opening 120 is to be formed, is formed on the passivation film 121 by the photolithography technique, for example, and this photoresist pattern is used as an etching mask to perform a dry etching using a fluorine-based gas or a chlorine-based gas. A wet etching using a fluoric acid, a buffered fluoric acid, or the like, may be performed in place of the dry etching.

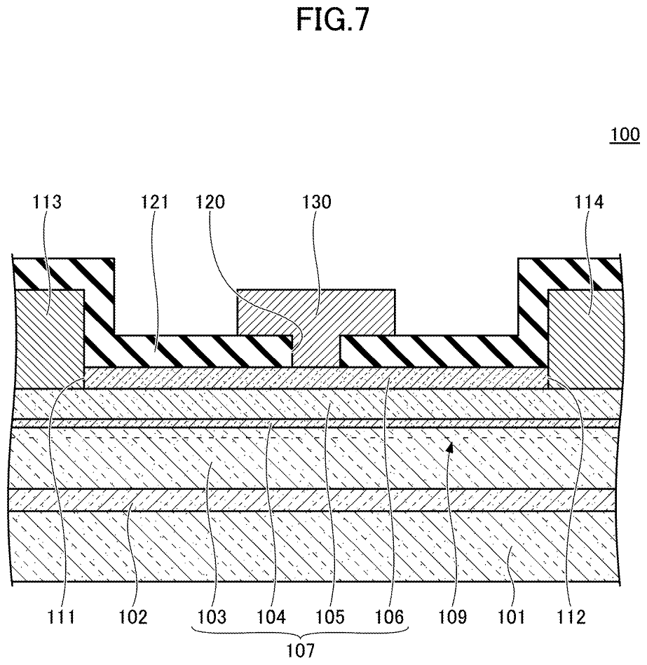

Next, as illustrated in FIG. 7, the gate electrode 130, which makes contact with the cap layer 106 via the opening 120, is formed on the passivation film 121 at a position between the source electrode 113 and the drain electrode 114. When forming the gate electrode 130, a resist film, having an opening in a region where the gate electrode 130 is to be formed, is provided by the photolithography technique. Then, the resist film is used as a deposition mask to form a metal film by deposition, and this resist film is removed together with the metal film thereon, for example, thereby forming the gate electrode 130 inside the opening in the resist film. In other words, the gate electrode 130 may be formed by the lift-off method. When forming the metal film, an Au film may be formed after forming a Ni film, for example.

The semiconductor device 100 according to the first embodiment can be manufactured by the processes (or steps) described above.

### Second Embodiment

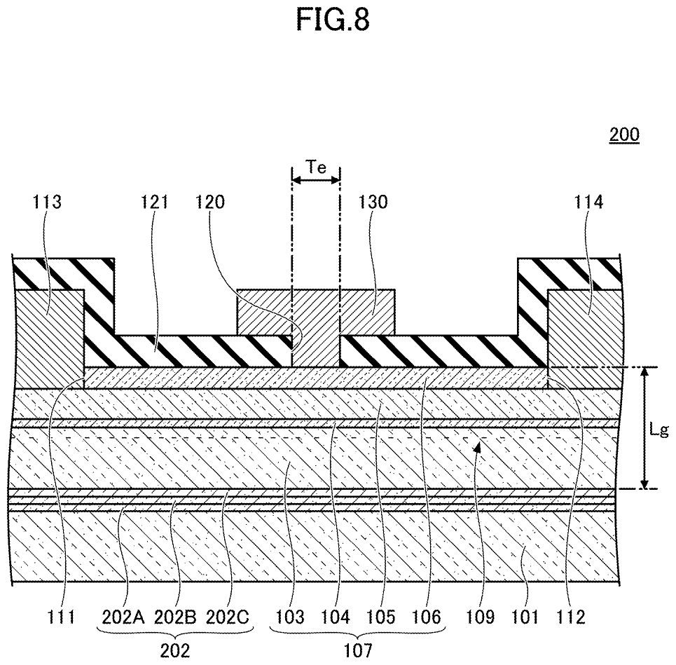

Next, a second embodiment will be described. The second embodiment relates to a semiconductor device including a HEMT, and mainly differs from the first embodiment in the buffer layer configuration. FIG. 8 is a cross sectional view illustrating the semiconductor device according to the second embodiment.

As illustrated in FIG. 8, a semiconductor device 200 according to the second embodiment includes a buffer layer 202 in place of the buffer layer 102 according to the first embodiment. A thickness of the buffer layer 202 may be 100 nm or less. The buffer layer 202 includes an Alₓ₁Ga₁₋ₓ₁N layer 202A formed on substrate 101, an Alₓ₂Ga₁₋ₓ₂N layer 202B formed on Alₓ₁Ga₁₋ₓ₁N layer 202A, and an Alₓ₃Ga₁₋ₓ₃N layer 202C formed on Alₓ₁Ga₁₋ₓ₂N layer 202B. An Al composition x1 of the Alₓ₁Ga₁₋ₓ₁N layer 202A is higher than an Al composition x2 of the Alₓ₂Ga₁₋ₓ₂N layer 202B, and the Al composition x2 of the Alₓ₂Ga₁₋ₓ₂N layer 202B is higher than an Al composition x3 of the Alₓ₃Ga₁₋ₓ₃N layer 202C. The Al composition x3 may be 0.2 or higher, for example.

For example, the dislocation densities of the Alₓ₁Ga₁₋ₓ₁N layer 202A, the Alₓ₂Ga₁₋ₓ₂N layer 202B, and the Alₓ₃Ga₁₋ₓ₃N layer 202C may be 10⁵ cm⁻² or less. In addition, the dislocation density of each of the Alₓ₁Ga₁₋ₓ₁N layer 202A, the Alₓ₂Ga₁₋ₓ₂N layer 202B, and the Alₓ₃Ga₁₋ₓ₃N layer 202C may be in a range of 10⁴ cm⁻² or greater and 10⁵ cm⁻² or less.

Other configurations of the second embodiment may be similar to those of the first embodiment.

The second embodiment can obtain advantageous features similar to the advantageous features obtainable by the first embodiment. In addition, because the buffer layer 202 includes three layers and the Al composition is higher toward the substrate 101 and the Al composition is lower toward the electron transit layer 103, a lattice matching can easily be achieved, and the back barrier function of the buffer layer 202 can be improved.

In the second embodiment, the number of AlGaN layers forming the buffer layer 202 is not particularly limited. The number of AlGaN layers may be two, or may be four or more.

In the present disclosure, the gate length Lg may be 0.3 μm or less. This is because a sufficiently high operation speed may not be obtained for the high-frequency operation, if the gate length Lg is greater than 0.3 μm. The gate length Lg may preferably be 0.2 μm or less, and more preferably 0.1 μm or less.

In the present disclosure, the ratio Te/Lg of the thickness Te of the semiconductor laminated structure with respect to the gate length Lg may be 4.0 or less, because the electrons bypassing near the lower surface of the electron transit layer may not be sufficiently reduced if the ratio (Te/Lg) is greater than 4.0. The ratio Te/Lg is preferably 3.5 or less, and more preferably 3.0 or less.

In the present disclosure, the Al composition of the buffer layer is preferably 0.2 or higher. This is because the electrons may bypass inside the buffer layer and generate the off-leak current if the Al composition is less than 0.2. For this reason, the Al composition of the buffer layer is preferably 0.2 or higher, more preferably 0.3 or higher, and even more preferably 0.4 or higher. From a viewpoint of the lattice matching between the buffer layer and the electron transit layer, the Al composition of the buffer layer is preferably 0.9 or lower, more preferably 0.8 or lower, and even more preferably 0.7 or lower.

In the present disclosure, the thickness of the buffer layer is preferably 100 nm or less, in order to obtain the back barrier effect of the AlN substrate. The thickness of the buffer layer is preferably 100 nm or less, more preferably 80 nm or less, and even more preferably 60 nm or less.

In a case where the electron transit layer 103 can be epitaxially grown on the substrate 101, the buffer layers 102 and 202 may be omitted. In other words, the lower surface of the electron transit layer 103 may make direct contact with the substrate 101.

Next, experiments conducted by the present inventors will be described.

### First Experiment

In a first experiment, the off-leak current was measured for each ratio Te/Lg, using a first structure in accordance with the first embodiment, and a second structure in accordance with the reference example.

In the first structure, an AlN substrate 101 was used as the substrate 101, and an AlGaN layer having a thickness of 60 nm and an Al composition x of 0.3 was used as the buffer layer 102. Six samples with different thickness Te of the semiconductor laminated structure 107 and gate length Lg of the gate electrode 130 were prepared, and the off-leak current was measured for each of the six samples.

In the second structure, a SiC substrate 901 was used as the substrate 901, and an AlGaN layer was used as the buffer layer 902 having a thickness of 300 nm and an Al composition x of 0.05. Five samples with different thickness Te of the semiconductor laminated structure 907 and gate length Lg of the gate electrode 930 were prepared, and the off-leak current was measured for each of the five samples.

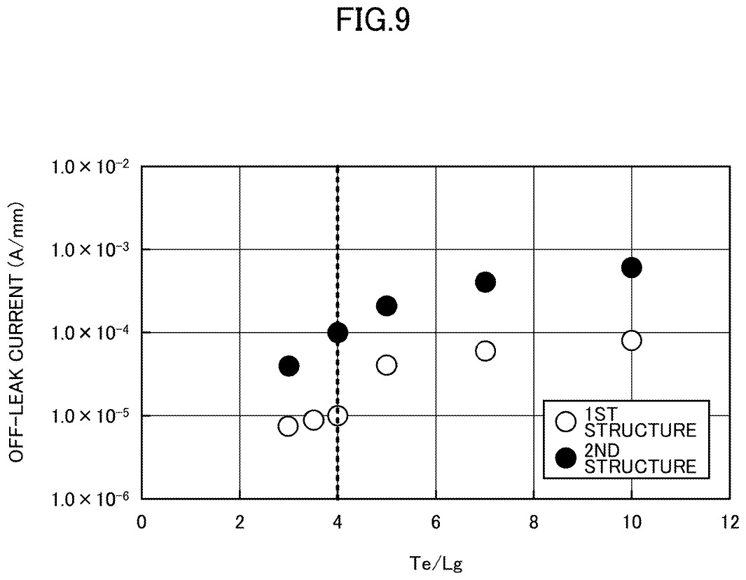

FIG. 9 is a diagram illustrating results of the first experiment. In FIG. 9, the abscissa indicates the ratio Te/Lg, and the ordinate indicates the off-leak current. As illustrated in FIG. 9, if the ratios Te/Lg are the same, the off-leak current in the first structure became smaller than the off-leak current in the second structure. Further, in the first structure, if the ratio Te/Lg was 4.0 or less, the off-leak current was 1.0×10⁻⁵ A/mm or less and considerably low.

### Second Experiment

In a second experiment, a drain current Id and a gate leak current Ig were measured when a source-gate voltage Vgs was varied for the sample (sample A) having the first structure with the ratio Te/Lg of 3.0, and the sample (sample B) having the second structure with the ratio Te/Lg of 10.0. The sample A has the thickness Te of 0.3 μm, and the gate length Lg of 0.1 μm. The sample B has the thickness Te of 1.0 μm, and the gate length Lg of 0.1 μm.

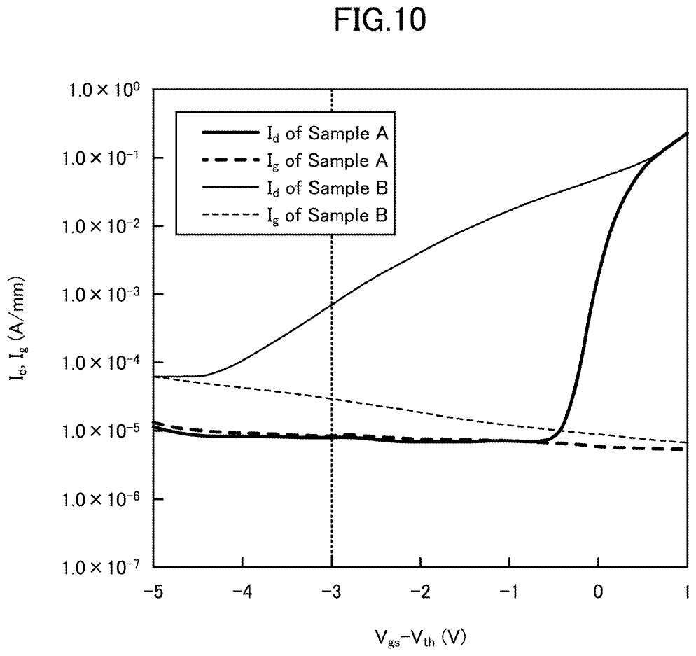

FIG. 10 is a diagram illustrating the results of the second experiment. In FIG. 10, the abscissa indicates a difference Vgs-Vth between the source-gate voltage Vgs and a threshold voltage Vth, and the ordinate indicates the drain current Id and the gate leak current Ig. As illustrated in FIG. 10, in a case where the samples assume the off state when the voltage difference Vgs−Vth becomes −3 V, the drain current Id of 6.1×10⁻⁴ A/mm flows in the sample B, while the drain current Id of only 7.6×10⁻⁶ A/mm flows in the sample A. Moreover, due to the back barrier effect, a gate leak current Ig of the sample A was smaller than the gate leak current Ig of the sample B.

### Third Experiment

In a third experiment, an extent of the current collapse was identified for the sample A and the sample B described above, and a sample (sample C) having the second structure with the ratio Te/Lg of 3.0. In other words, the source-gate voltage Vgs was set to 2 V, a relationship between a source-drain voltage Vds and the drain current Id was measured, with and without an applied bias stress, and a ratio of the drain current Id with the applied bias stress with respect to the drain current Id without the applied bias stress was calculated for a case where the source-to-drain voltage Vds is 7 V.

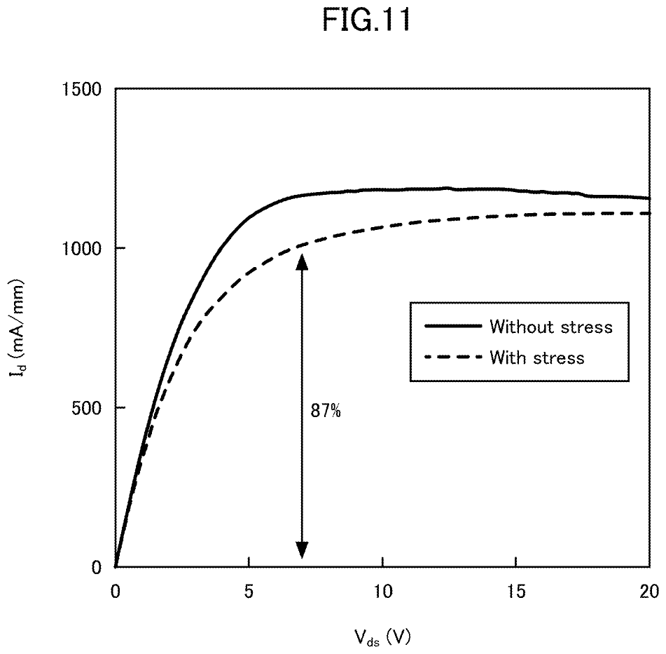

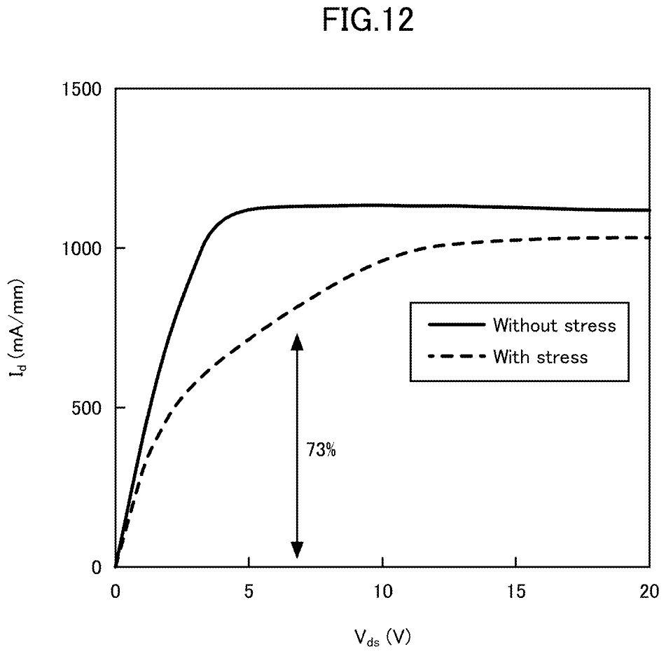

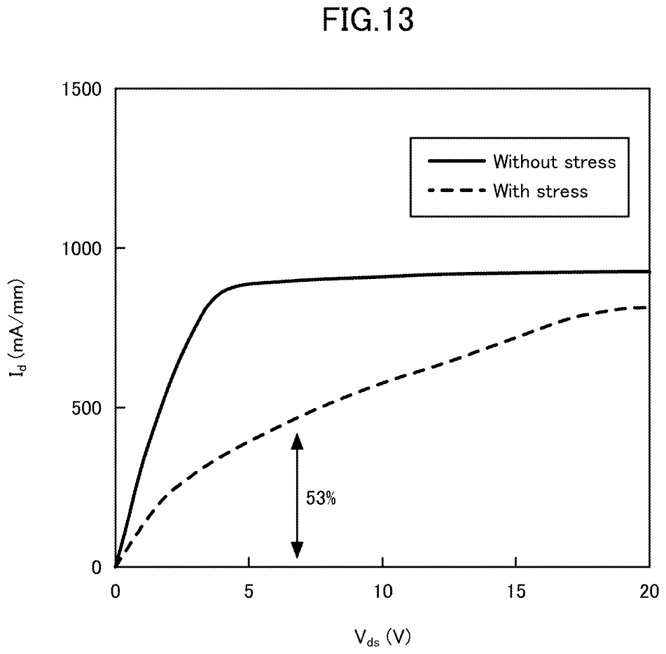

FIG. 11 illustrates the results of the third experiment conducted on the sample A, FIG. 12 illustrates the results of the third experiment conducted on the sample B, and FIG. 13 illustrates the results of the third experiment conducted on the sample C. In FIG. 11 through FIG. 13, the abscissa indicates the source-drain voltage Vds, and the ordinate indicates the drain current Id. As illustrated in FIG. 11, in the sample A, the source-to-drain voltage Vds was 7 V, and the ratio (or collapse rate) of the drain current Id with the applied bias stress with respect to the drain current Id without the applied bias stress was 87%. In sample B, the collapse rate was 73%, and in sample C, the collapse rate was 53%.

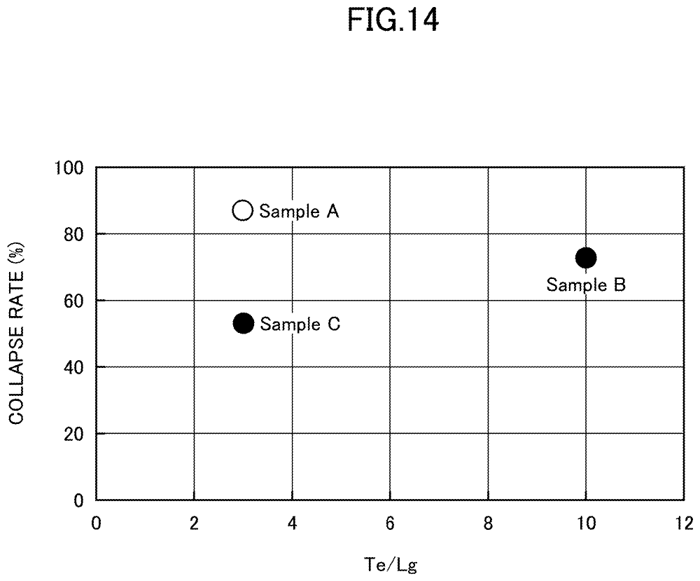

FIG. 14 is a diagram illustrating the collapse rates of the sample A, the sample B, and the sample C. In FIG. 14, the abscissa indicates the ratio Te/Lg, and the ordinate indicates the collapse rate. As illustrated in FIG. 14, between the sample B and the sample C belonging to the second structure, the collapse rate was small and the current collapse was notable for the sample C having the small ratio Te/Lg.

### Third Embodiment

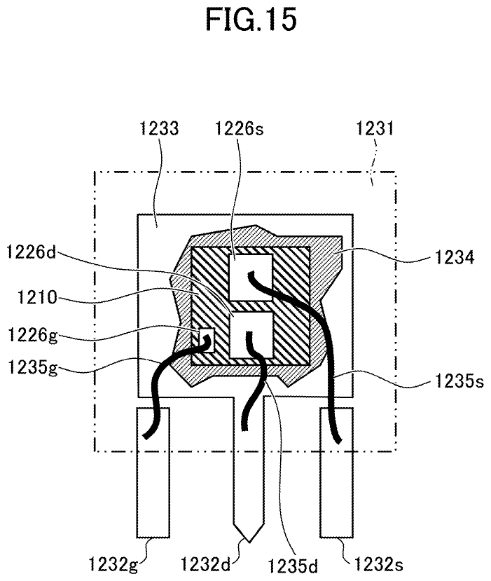

Next, a third embodiment will be described. The third embodiment relates to a discrete package of the HEMT. FIG. 15 is a diagram illustrating a discrete package according to the third embodiment.

In the third embodiment, as illustrated in FIG. 15, a back surface of a semiconductor device, 1210 having a structure similar to the structure of either one of the first and second embodiments, is fixed to a land (or die pad) 1233 using a die attach adhesive 1234, such as a solder or the like. One end of a wire 1235d, such as an Al wire or the like, is connected to a drain pad 1226d which is connected to the drain electrode 114. The other end of the wire 1235d is connected to a drain lead 1232d which is integral with the land 1233. One end of a wire 1235s, such as an Al wire or the like, is connected to a source pad 1226s which is connected to the source electrode 113. The other end of the wire 1235s is connected to a source lead 1232s which is independent of the land 1233. One end of a wire 1235g, such as an Al wire or the like, is connected to a gate pad 1226g which is connected to the gate electrode 130. The other end of the wire 1235g is connected to a gate lead 1232g which is independent of the land 1233. The land 1233, the semiconductor device 1210, or the like are formed into a package by a mold resin 1231, so that a portion of the gate lead 1232g, a portion of the drain lead 1232d, and a portion of the source lead 1232s protrude from the package.

Such a discrete package may be manufactured in the following manner, for example. First, the semiconductor device 1210 is fixed to the land 1233 of a lead frame using the die attach adhesive 1234, such as the solder or the like. Next, the gate pad 1226g is connected to the gate lead 1232g of the lead frame, by bonding using the wires 1235g, 1235d and 1235s. The drain pad 1226d is connected to the drain lead 1232d of the lead frame, and the source pad 1226s is connected to the source lead 1232s of the lead frame. Thereafter, an encapsulation using the mold resin 1231 is performed by transfer molding. The lead frame is then disconnected from the package.

### Fourth Embodiment

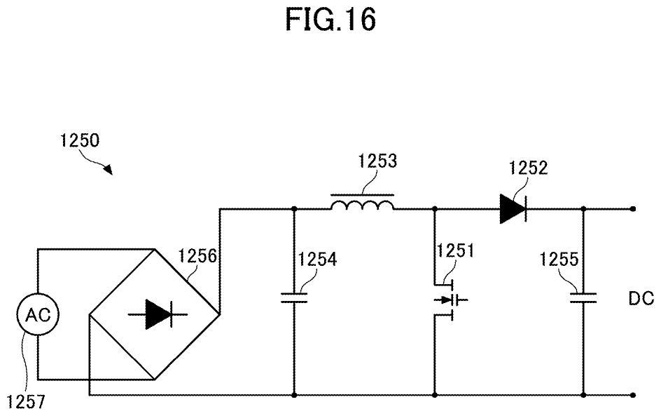

Next, a fourth embodiment will be described. The fourth embodiment relates to a Power Factor Correction (PFC) circuit including the HEMT. FIG. 16 is a circuit diagram illustrating the PFC circuit according to the fourth embodiment.

A PFC circuit 1250 includes a switching device (transistor) 1251, a diode 1252, a choke coil 1253, capacitors 1254 and 1255, a diode bridge 1256, and an AC power supply 1257. A drain electrode of the switching device 1251 is connected to an anode terminal of the diode 1252 and to one terminal of the choke coil 1253. A source electrode of the switching device 1251 is connected to one terminal of the capacitor 1254 and to one terminal of the capacitor 1255. The other terminal of the capacitor 1254 is connected to the other terminal of choke coil 1253. The other terminal of capacitor 1255 is connected to a cathode terminal of the diode 1252 are connected. In addition, a gate driver is connected to a gate electrode of the switching device 1251. The AC power supply 1257 is connected between the terminals of the capacitor 1254, via the diode bridge 1256. A DC power supply is connected between the terminals of capacitor 1255. In this embodiment, a semiconductor device having a structure similar to the structure or either one of the first and second embodiments is used for the switching device 1251.

When manufacturing the PFC circuit 1250, the switching device 1251 is connected to the diode 1252, the choke coil 1253, or the like, using a solder or the like, for example.

### Fifth Embodiment

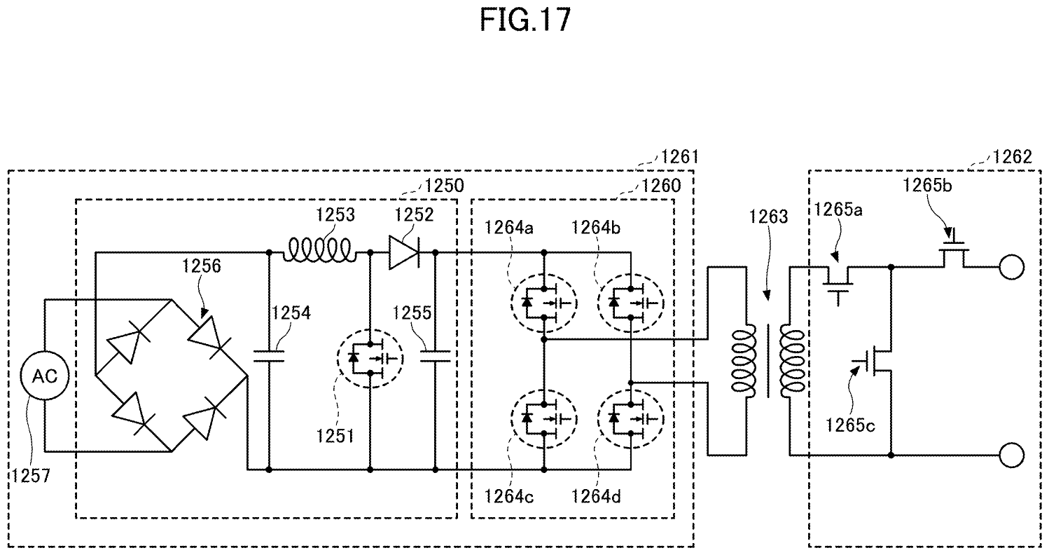

Next, a fifth embodiment will be described. The fifth embodiment relates to a power supply including the HEMT, suitable for use as a server power supply. FIG. 17 is a circuit diagram illustrating a power supply according to the fifth embodiment.

The power supply includes a high-voltage primary circuit 1261, a low-voltage secondary circuit 1262, and a transformer 1263 arranged between the primary circuit 1261 and the secondary circuit 1262.

The primary circuit 1261 includes the PFC circuit 1250 according to the fourth embodiment, and an inverter circuit, such as a full bridge inverter circuit 1260, connected between the terminals of the capacitor 1255 of the PFC circuit 1250. The full bridge inverter circuit 1260 includes a plurality of (four in this example) switching devices 1264a, 1264b, 1264c, and 1264d.

The secondary circuit 1262 includes a plurality of (three in this example) switching devices 1265a, 1265b, and 1265c.

In this embodiment, a semiconductor device having a structure similar to the structure of either one of the first and second embodiments is used for each of the switching device 1251 of the PFC circuit 1250, forming the primary circuit 1261, and the switching devices 1264a, 1264b, 1264c, and 1264d of the full bridge inverter circuit 1260. On the other hand, existing MIS type field effect transistors (FETs) using silicon are used for each of the switching devices 1265a, 1265b, and 1265c of the secondary circuit 1262.

### Sixth Embodiment

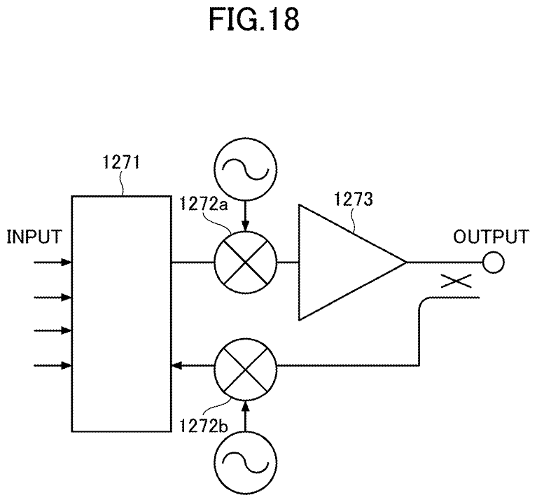

Next, a sixth embodiment will be described. The sixth embodiment relates to an amplifier including the HEMT. FIG. 18 is a circuit diagram illustrating the amplifier according to the sixth embodiment.

The amplifier includes a digital predistortion circuit 1271, mixers 1272a and 1272b, and a power amplifier 1273.

The digital predistortion circuit 1271 compensates for a nonlinear distortion of an input signal. The mixer 1272a mixes input signal, compensated of the non-linear distortion, and an AC signals, into a mixed signal. The power amplifier 1273 includes a semiconductor device having a structure similar to the structure of either one of the first and second embodiments, and is configured to amplify the AC signal and the mixed input signal. In this embodiment, an output signal can be mixed with the AC signal by the mixer 1272b, and a mixed signal can be transmitted to the digital predistortion circuit 1271, by the switching of switching devices, for example. The amplifier may be used as a high-frequency amplifier or a high-power amplifier. The high-frequency amplifier may be used in transmitters and receivers for cellular base stations, radar devices, and microwave generators, for example.

In the present disclosure, the structures of the gate electrode, the source electrode, and the drain electrode are not limited to those of the embodiments described above. For example, these electrodes may be formed of a single layer. In addition, the method of forming these electrodes is not limited to the lift-off method. Further, if ohmic properties can be obtained, the heat treatment after forming the source electrode and the drain electrode may be omitted. The heat treatment may be performed after forming the gate electrode.

The Schottky type gate structure is used for the gate electrode in the embodiments described above, however, a Metal-Insulator-Semiconductor (MIS) type gate structure may be used for the gate electrode.

The compositions of the nitride semiconductor layers included in the semiconductor laminated structure are not limited to those of the embodiments described above. For example, nitride semiconductors, such as InAlN, InGaAlN, or the like, may be used.

Moreover, the buffer layer, disposed between the substrate and the electron transit layer, may be made of AlₓGa_{1.0-x}N, where 0.0<=x<=1.0, for example.

In addition, the sequence of processes (or steps) of the method for manufacturing the semiconductor device according to the present disclosure is not limited to that of the embodiments described above. For example, a passivation film may be formed before forming the source electrode and the drain electrode.

According to the present disclosure, it is possible to reduce the off-leak current and the current collapse.

Although the embodiments are numbered with, for example, “first,” “second,” “third,” “fourth,” “fifth,” or “sixth,” the ordinal numbers do not imply priorities of the embodiments. Many other variations and modifications will be apparent to those skilled in the art.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor device comprising:
an AlN substrate;
a semiconductor laminated structure, disposed above the substrate, and including an electron transit layer and an electron supply layer made of a nitride semiconductor, respectively; and
a gate electrode, a source electrode, and a drain electrode disposed above the electron supply layer, wherein
the electron transit layer is located at a lowermost position of the semiconductor laminated structure,
the gate electrode has a gate length of 0.3 μm or less, and
a ratio of a thickness of the semiconductor laminated structure with respect to the gate length of the gate electrode is 4.0 or less.

2. The semiconductor device as claimed in claim 1, further comprising:
a buffer layer made of AlₓGa_{1.0-x}N and disposed between the substrate and the electron transit layer, where 0.0<=x<=1.0.

3. The semiconductor device as claimed in claim 2, wherein an Al composition x of the buffer layer is 0.2 or higher.

4. The semiconductor device as claimed in claim 2, wherein the buffer layer includes
a first buffer layer having a first Al composition, and
a second buffer layer disposed above the first buffer layer and having a second Al composition lower than the first Al composition.

5. The semiconductor device as claimed in claim 3, wherein the buffer layer includes
a first buffer layer having a first Al composition, and
a second buffer layer disposed above the first buffer layer and having a second Al composition lower than the first Al composition.

6. The semiconductor device as claimed in claim 2, wherein a thickness of the buffer layer is 100 nm or less.

7. The semiconductor device as claimed in claim 3, wherein a thickness of the buffer layer is 100 nm or less.

8. The semiconductor device as claimed in claim 4, wherein a thickness of the buffer layer is 100 nm or less.

9. The semiconductor device as claimed in claim 2, wherein a dislocation density of the buffer layer is 1.0×10³ cm⁻² or less.

10. The semiconductor device as claimed in claim 3, wherein a dislocation density of the buffer layer is 1.0×10³ cm⁻² or less.

11. The semiconductor device as claimed in claim 4, wherein a dislocation density of the buffer layer is 1.0×10³ cm⁻² or less.

12. The semiconductor device as claimed in claim 5, wherein a dislocation density of the buffer layer is 1.0×10³ cm⁻² or less.

13. The semiconductor device as claimed in claim 1, wherein a lower surface of the electron transit layer makes direct contact with the substrate.

14. A method for manufacturing a semiconductor device comprising:
forming a semiconductor laminated structure, including an electron transit layer and an electron supplying layer, above an AlN substrate;
forming a gate electrode, a source electrode, and a drain electrode above the electron supply layer, wherein
the electron transit layer is located at a lowermost position of the semiconductor laminated structure,
the gate electrode has a gate length of 0.3 μm or less, and
a ratio of a thickness of the semiconductor laminated structure with respect to the gate length of the gate electrode is 4.0 or less.

15. The method for manufacturing the semiconductor device as claimed in claim 14, further comprising:
forming a buffer layer above the substrate before the forming the semiconductor laminated structure,
wherein the forming the semiconductor laminated structure forms the semiconductor laminated structure on the buffer layer.

16. The method for manufacturing the semiconductor device as claimed in claim 15, wherein the forming the buffer layer forms the buffer layer having an Al composition x which is 0.2 or higher.

17. The method for manufacturing the semiconductor device as claimed in claim 15, wherein the forming the buffer layer forms the buffer layer made of AlₓGa_{1.0-x}N, between the substrate and the electron transit layer, where 0.0<=x<=1.0.

18. The method for manufacturing the semiconductor device as claimed in claim 17, wherein the forming the buffer layer includes
forming a first buffer layer having a first Al composition, and
forming a second buffer layer above the first buffer layer and having a second Al composition lower than the first Al composition.

19. The method for manufacturing the semiconductor device as claimed in claim 14, wherein the forming the semiconductor laminated structure forms the semiconductor laminated structure including the electron transit layer and the electron supply layer made of a nitride semiconductor, respectively, so that a lower surface of the electron transit layer makes direct contact with the substrate.
